(19) United States
(12) Patent Application Publication
(10) Pub. No.: US 2015/0097801 A1
(43) Pub. Date: Apr. 9, 2015

(54) TOUCH-SENSOR ELECTRODE DETAILS

(71) Applicants: Matthew TREND, Fareham (GB); Carl Carley, Basingstoke (GB)

(72) Inventors: Matthew TREND, Fareham (GB); Carl Carley, Basingstoke (GB)

(21) Appl. No.: 14/049,048

(22) Filed: Oct. 8, 2013

(51) Int. Cl. G06F 3/046; H05K 3/16; H05K 3/14

(52) U.S. Cl. CPC G06F 3/046; H05K 3/146; H05K 3/16
USPC 345/174; 29/846

(57) ABSTRACT

In one embodiment, a touch sensor includes a drive electrode and a sense electrode. The sense electrode is separated from the drive electrode by a gap having a width, and the width of the gap is substantially uniform throughout the entire extent of the gap.

### TECHNICAL FIELD

This disclosure generally relates to touch sensors.

### BACKGROUND

A touch sensor may detect the presence and location of a touch or the proximity of an object (such as a user's finger or a stylus) within a touch-sensitive area of the touch sensor overlaid on a display screen, for example. In a touch-sensitive-display application, the touch sensor may enable a user to interact directly with what is displayed on the screen, rather than indirectly with a mouse or touch pad. A touch sensor may be attached to or provided as part of a desktop computer, laptop computer, tablet computer, personal digital assistant (PDA), smartphone, satellite navigation device, portable media player, portable game console, kiosk computer, point-of-sale device, or other suitable device. A control panel on a household or other appliance may include a touch sensor.

There are a number of different types of touch sensors, such as (for example) resistive touch screens, surface acoustic wave touch screens, and capacitive touch screens. Herein, reference to a touch sensor may encompass a touch screen, and vice versa, where appropriate. When an object touches or comes within proximity of the surface of the capacitive touch screen, a change in capacitance may occur within the touch screen at the location of the touch or proximity. A touch-sensor controller may process the change in capacitance to determine its position on the touch screen.

### BRIEF DESCRIPTION OF THE DRAWINGS

FIG. 1 illustrates an example sensor with an example sensor controller.

FIGS. 2A and 2B illustrate example electrodes for an example touch sensor.

FIG. 3 illustrates another array of example electrodes for an example touch sensor.

FIG. 4 illustrates another array of example electrodes for an example touch sensor.

FIG. 5 illustrates an example method for forming drive and sense electrodes.

### DESCRIPTION OF EXAMPLE EMBODIMENTS

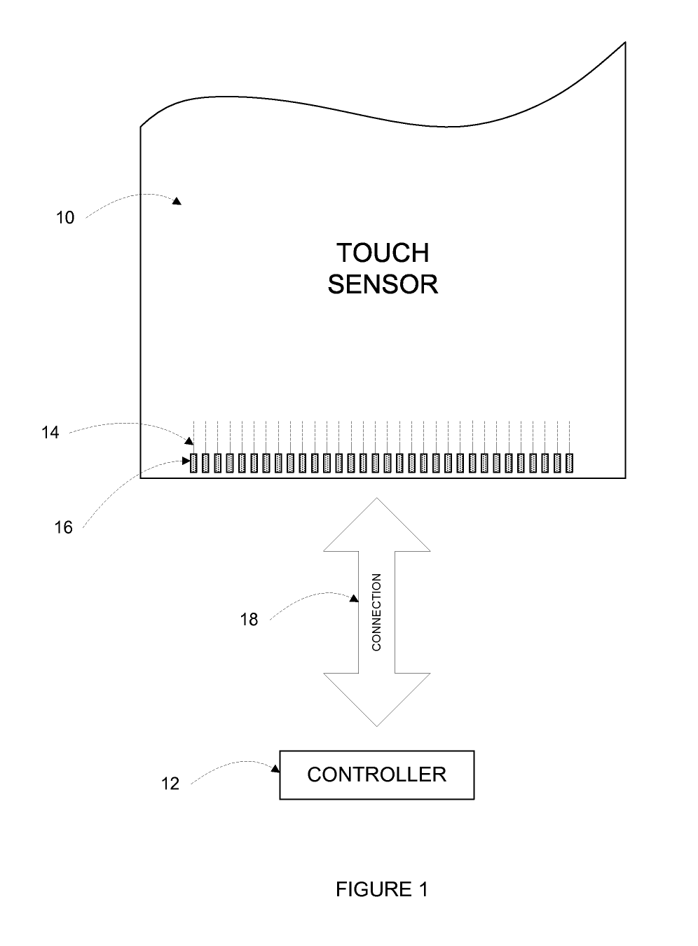

FIG. 1 illustrates an example touch sensor 10 with an example touch-sensor controller 12. Touch sensor 10 and touch-sensor controller 12 may detect the presence and location of a touch or the proximity of an object within a touch-sensitive area of touch sensor 10. Herein, reference to a touch sensor may encompass both the touch sensor and its touch-sensor controller, where appropriate. Similarly, reference to a touch-sensor controller may encompass both the touch-sensor controller and its touch sensor, where appropriate. Touch sensor 10 may include one or more touch-sensitive areas, where appropriate. Touch sensor 10 may include an array of drive and sense electrodes (or an array of electrodes of a single type) disposed on one or more substrates, which may be made of a dielectric material. Herein, reference to a touch sensor may encompass both the electrodes of the touch sensor and the substrate(s) that they are disposed on, where appropriate. Alternatively, where appropriate, reference to a touch sensor may encompass the electrodes of the touch sensor, but not the substrate(s) that they are disposed on.

An electrode (whether a ground electrode, a guard electrode, a drive electrode, or a sense electrode) may be an area of conductive material forming a shape, such as for example a disc, square, rectangle, thin line, other suitable shape, or suitable combination of these. One or more cuts in one or more layers of conductive material may (at least in part) create the shape of an electrode, and the area of the shape may (at least in part) be bounded by those cuts. In particular embodiments, the conductive material of an electrode may occupy approximately 100% of the area of its shape. As an example and not by way of limitation, an electrode may be made of indium tin oxide (ITO) and the ITO of the electrode may occupy approximately 100% of the area of its shape (sometimes referred to as 100% fill), where appropriate. In particular embodiments, the conductive material of an electrode may occupy substantially less than 100% of the area of its shape. As an example and not by way of limitation, an electrode may be made of fine lines of metal or other conductive material (FLM), such as for example copper, silver, or a copper- or silver-based material, and the fine lines of conductive material may occupy approximately 5% of the area of its shape in a hatched, mesh, or other suitable pattern. Herein, reference to FLM encompasses such material, where appropriate. Although this disclosure describes or illustrates particular electrodes made of particular conductive material forming particular shapes with particular fill percentages having particular patterns, this disclosure contemplates any suitable electrodes made of any suitable conductive material forming any suitable shapes with any suitable fill percentages having any suitable patterns.

Where appropriate, the shapes of the electrodes (or other elements) of a touch sensor may constitute in whole or in part one or more macro-features of the touch sensor. One or more characteristics of the implementation of those shapes (such as, for example, the conductive materials, fills, or patterns within the shapes) may constitute in whole or in part one or more micro-features of the touch sensor. One or more macro-features of a touch sensor may determine one or more characteristics of its functionality, and one or more micro-features of the touch sensor may determine one or more optical features of the touch sensor, such as transmittance, refraction, or reflection.

A mechanical stack may contain the substrate (or multiple substrates) and the conductive material forming the drive or sense electrodes of touch sensor 10. As an example and not by way of limitation, the mechanical stack may include a first layer of optically clear adhesive (OCA) beneath a cover panel. The cover panel may be clear and made of a resilient material suitable for repeated touching, such as for example glass, polycarbonate, or poly(methyl methacrylate) (PMMA). This disclosure contemplates any suitable cover panel made of any suitable material. The first layer of OCA may be disposed between the cover panel and the substrate with the conductive material forming the drive or sense electrodes. The mechanical stack may also include a second layer of OCA and a dielectric layer (which may be made of PET or another suitable material, similar to the substrate with the conductive material forming the drive or sense electrodes). As an alternative, where appropriate, a thin coating of a dielectric material may be applied instead of the second layer of OCA and the dielectric layer. The second layer of OCA may be disposed between the substrate with the conductive material making up the drive or sense electrodes and the dielectric layer, and the dielectric layer may be disposed between the second layer of OCA and an air gap to a display of a device including touch sensor 10 and touch-sensor controller 12. As an example only and not by way of limitation, the cover panel may have a thickness of approximately 1 mm; the first layer of OCA may have a thickness of approximately 0.05 mm; the substrate with the conductive material forming the drive or sense electrodes may have a thickness of approximately 0.05 mm; the second layer of OCA may have a thickness of approximately 0.05 mm; and the dielectric layer may have a thickness of approximately 0.05 mm. Although this disclosure describes a particular mechanical stack with a particular number of particular layers made of particular materials and having particular thicknesses, this disclosure contemplates any suitable mechanical stack with any suitable number of any suitable layers made of any suitable materials and having any suitable thicknesses. As an example and not by way of limitation, in particular embodiments, a layer of adhesive or dielectric may replace the dielectric layer, second layer of OCA, and air gap described above, with there being no air gap to the display.

One or more portions of the substrate of touch sensor 10 may be made of polyethylene terephthalate (PET) or another suitable material. This disclosure contemplates any suitable substrate with any suitable portions made of any suitable material. In particular embodiments, the drive or sense electrodes in touch sensor 10 may be made of ITO in whole or in part. In particular embodiments, the drive or sense electrodes in touch sensor 10 may be made of fine lines of metal or other conductive material. As an example and not by way of limitation, one or more portions of the conductive material may be copper or copper-based and have a thickness of approximately 5 μm or less and a width of approximately 10 μm or less. As another example, one or more portions of the conductive material may be silver or silver-based and similarly have a thickness of approximately 5 μm or less and a width of approximately 10 μm or less. This disclosure contemplates any suitable electrodes made of any suitable material.

Touch sensor 10 may implement a capacitive form of touch sensing. In a mutual-capacitance implementation, touch sensor 10 may include an array of drive and sense electrodes forming an array of capacitive nodes. A drive electrode and a sense electrode may form a capacitive node. The drive and sense electrodes forming the capacitive node may come near each other, but not make electrical contact with each other. Instead, the drive and sense electrodes may be capacitively coupled to each other across a space, or gap, between them. A pulsed or alternating voltage applied to the drive electrode (by touch-sensor controller 12) may induce a charge on the sense electrode, and the amount of charge induced may be susceptible to external influence (such as a touch or the proximity of an object). When an object touches or comes within proximity of the capacitive node, a change in capacitance may occur at the capacitive node and touch-sensor controller 12 may measure the change in capacitance. By measuring changes in capacitance throughout the array, touch-sensor controller 12 may determine the position of the touch or proximity within the touch-sensitive area(s) of touch sensor 10.

In a self-capacitance implementation, touch sensor 10 may include an array of electrodes of a single type that may each form a capacitive node. When an object touches or comes within proximity of the capacitive node, a change in self-capacitance may occur at the capacitive node and touch-sensor controller 12 may measure the change in capacitance, for example, as a change in the amount of charge needed to raise the voltage at the capacitive node by a pre-determined amount. As with a mutual-capacitance implementation, by measuring changes in capacitance throughout the array, touch-sensor controller 12 may determine the position of the touch or proximity within the touch-sensitive area(s) of touch sensor 10. This disclosure contemplates any suitable form of capacitive touch sensing, where appropriate.

In particular embodiments, one or more drive electrodes may together form a drive line running horizontally or vertically or in any suitable orientation. Similarly, one or more sense electrodes may together form a sense line running horizontally or vertically or in any suitable orientation. In particular embodiments, drive lines may run substantially perpendicular to sense lines. Herein, reference to a drive line may encompass one or more drive electrodes making up the drive line, and vice versa, where appropriate. Similarly, reference to a sense line may encompass one or more sense electrodes making up the sense line, and vice versa, where appropriate.

Touch sensor 10 may have drive and sense electrodes disposed in a pattern on one side of a single substrate. In such a configuration, a pair of drive and sense electrodes capacitively coupled to each other across a space between them may form a capacitive node. For a self-capacitance implementation, electrodes of only a single type may be disposed in a pattern on a single substrate. In addition or as an alternative to having drive and sense electrodes disposed in a pattern on one side of a single substrate, touch sensor 10 may have drive electrodes disposed in a pattern on one side of a substrate and sense electrodes disposed in a pattern on another side of the substrate. Moreover, touch sensor 10 may have drive electrodes disposed in a pattern on one side of one substrate and sense electrodes disposed in a pattern on one side of another substrate. In such configurations, an intersection of a drive electrode and a sense electrode may form a capacitive node. Such an intersection may be a location where the drive electrode and the sense electrode “cross” or come nearest each other in their respective planes. The drive and sense electrodes do not make electrical contact with each other—instead they are capacitively coupled to each other across a dielectric at the intersection. Although this disclosure describes particular configurations of particular electrodes forming particular nodes, this disclosure contemplates any suitable configuration of any suitable electrodes forming any suitable nodes. Moreover, this disclosure contemplates any suitable electrodes disposed on any suitable number of any suitable substrates in any suitable patterns.

As described above, a change in capacitance at a capacitive node of touch sensor 10 may indicate a touch or proximity input at the position of the capacitive node. Touch-sensor controller 12 may detect and process the change in capacitance to determine the presence and location of the touch or proximity input. Touch-sensor controller 12 may then communicate information about the touch or proximity input to one or more other components (such as one or more central processing units (CPUs)) of a device that includes touch sensor 10 and touch-sensor controller 12, which may respond to the touch or proximity input by initiating a function of the device (or an application running on the device). Although this disclosure describes a particular touch-sensor controller having particular functionality with respect to a particular device and a particular touch sensor, this disclosure contemplates any suitable touch-sensor controller having any suitable functionality with respect to any suitable device and any suitable touch sensor.

Touch-sensor controller 12 may be one or more integrated circuits (ICs), such as for example general-purpose microprocessors, microcontrollers, programmable logic devices or arrays, application-specific ICs (ASICs). In particular embodiments, touch-sensor controller 12 comprises analog circuitry, digital logic, and digital non-volatile memory. In particular embodiments, touch-sensor controller 12 is disposed on a flexible printed circuit (FPC) bonded to the substrate of touch sensor 10, as described below. The FPC may be active or passive, where appropriate. In particular embodiments, multiple touch-sensor controllers 12 are disposed on the FPC. Touch-sensor controller 12 may include a processor unit, a drive unit, a sense unit, and a storage unit. The drive unit may supply drive signals to the drive electrodes of touch sensor 10. The sense unit may sense charge at the capacitive nodes of touch sensor 10 and provide measurement signals to the processor unit representing capacitances at the capacitive nodes. The processor unit may control the supply of drive signals to the drive electrodes by the drive unit and process measurement signals from the sense unit to detect and process the presence and location of a touch or proximity input within the touch-sensitive area(s) of touch sensor 10. The processor unit may also track changes in the position of a touch or proximity input within the touch-sensitive area(s) of touch sensor 10. The storage unit may store programming for execution by the processor unit, including programming for controlling the drive unit to supply drive signals to the drive electrodes, programming for processing measurement signals from the sense unit, and other suitable programming, where appropriate. Although this disclosure describes a particular touch-sensor controller having a particular implementation with particular components, this disclosure contemplates any suitable touch-sensor controller having any suitable implementation with any suitable components.

Tracks 14 of conductive material disposed on the substrate of touch sensor 10 may couple the drive or sense electrodes of touch sensor 10 to connection pads 16, also disposed on the substrate of touch sensor 10. As described below, connection pads 16 facilitate coupling of tracks 14 to touch-sensor controller 12. Tracks 14 may extend into or around (e.g. at the edges of) the touch-sensitive area(s) of touch sensor 10. Particular tracks 14 may provide drive connections for coupling touch-sensor controller 12 to drive electrodes of touch sensor 10, through which the drive unit of touch-sensor controller 12 may supply drive signals to the drive electrodes. Other tracks 14 may provide sense connections for coupling touch-sensor controller 12 to sense electrodes of touch sensor 10, through which the sense unit of touch-sensor controller 12 may sense charge at the capacitive nodes of touch sensor 10. Tracks 14 may be made of fine lines of metal or other conductive material. As an example and not by way of limitation, the conductive material of tracks 14 may be copper or copper-based and have a width of approximately 100 μm or less. As another example, the conductive material of tracks 14 may be silver or silver-based and have a width of approximately 100 μm or less. In particular embodiments, tracks 14 may be made of ITO in whole or in part in addition or as an alternative to fine lines of metal or other conductive material. Although this disclosure describes particular tracks made of particular materials with particular widths, this disclosure contemplates any suitable tracks made of any suitable materials with any suitable widths. In addition to tracks 14, touch sensor 10 may include one or more ground lines terminating at a ground connector (which may be a connection pad 16) at an edge of the substrate of touch sensor 10 (similar to tracks 14).

Connection pads 16 may be located along one or more edges of the substrate, outside the touch-sensitive area(s) of touch sensor 10. As described above, touch-sensor controller 12 may be on an FPC. Connection pads 16 may be made of the same material as tracks 14 and may be bonded to the FPC using an anisotropic conductive film (ACF). Connection 18 may include conductive lines on the FPC coupling touch-sensor controller 12 to connection pads 16, in turn coupling touch-sensor controller 12 to tracks 14 and to the drive or sense electrodes of touch sensor 10. In another embodiment, connection pads 16 may be connected to an electro-mechanical connector (such as a zero insertion force wire-to-board connector); in this embodiment, connection 18 may not need to include an FPC. This disclosure contemplates any suitable connection 18 between touch-sensor controller 12 and touch sensor 10.

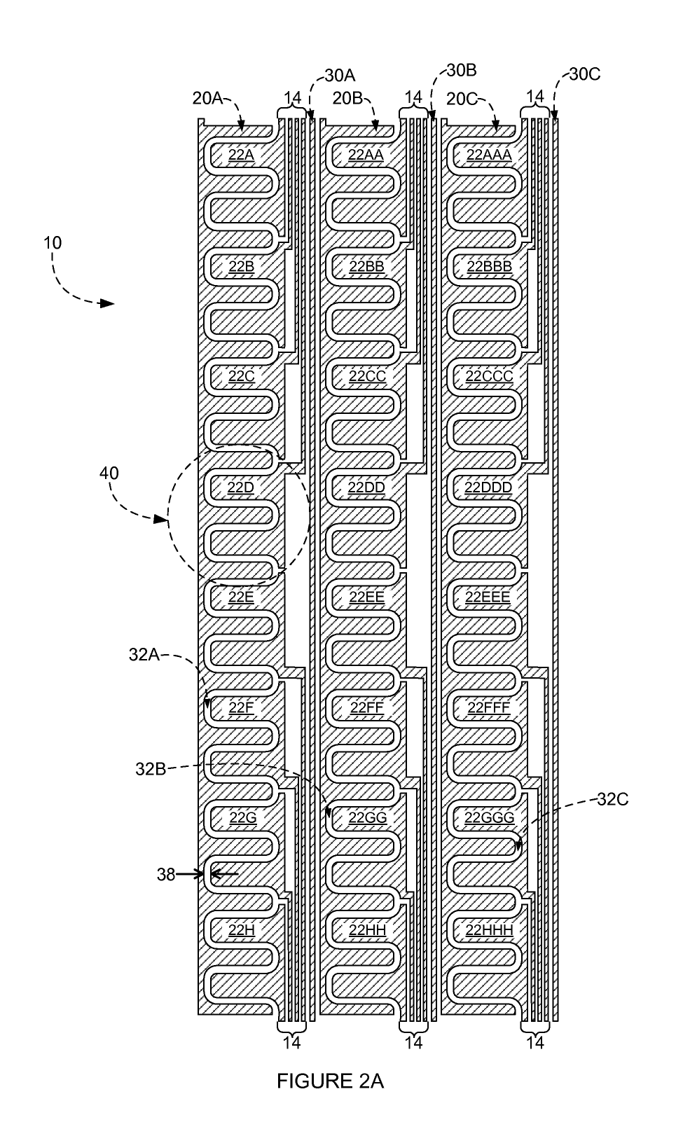

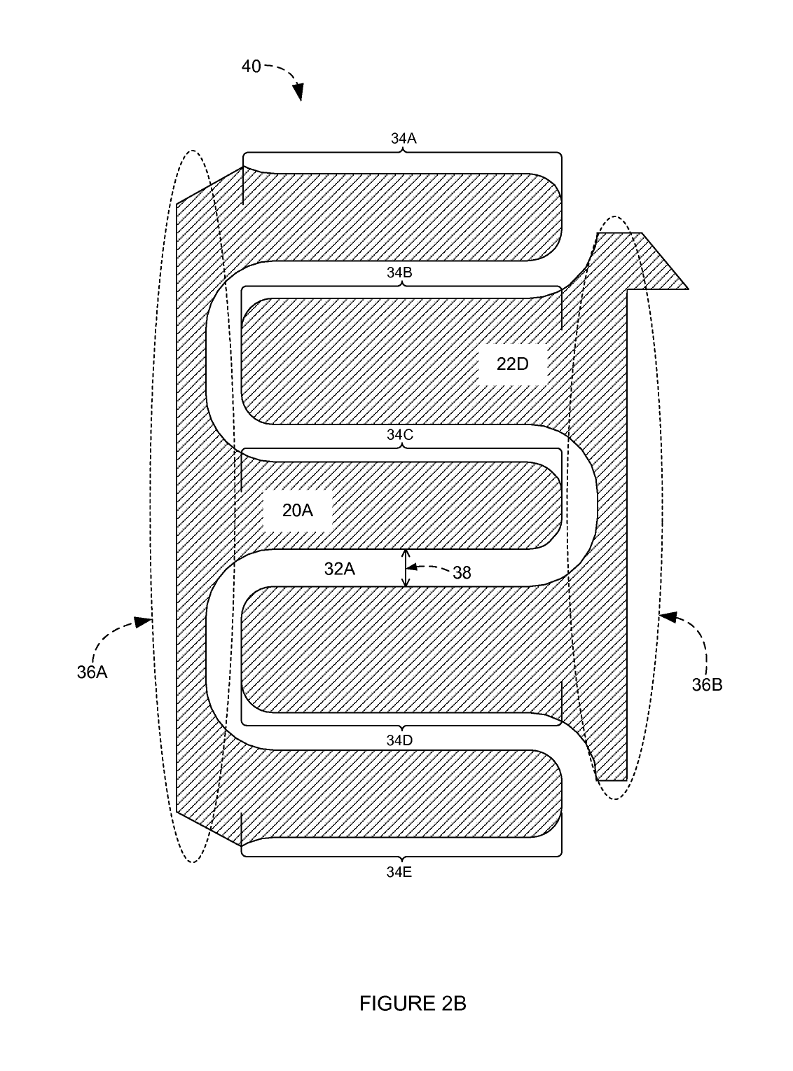

FIG. 2A illustrates example electrodes for an example touch sensor 10. In the example of FIG. 2A, touch sensor 10 includes an array of one or more drive electrodes 20 and one or more sense electrodes 22 defining a touch-sensitive area of touch sensor 10. As discussed above, tracks 14 of conductive material may couple drive or sense electrodes of touch sensor 10 to connection pads 16. A column of the array includes a drive electrode 20 extending along an axis corresponding to the column of the array. Each column also includes one or more sense electrodes 22 disposed in parallel and adjacent to its corresponding drive electrode 20. As an example and not by way of limitation, a column of the array includes drive electrode 20A with corresponding sense electrodes 22A-H disposed along an axis parallel to drive electrode 20A. One or more sense electrodes 22 may define rows that are substantially perpendicular to columns of the array. As an example and not by way of limitation, sense electrodes 22F-FFF may define a row of the array. As discussed above, a drive electrode 20 and an adjacent sense electrode 22 may form a capacitive node and may be capacitively coupled to each other across a region, space, or gap 32, between them. In particular embodiments, a gap region 32 may be referred to as a gap 32. As an example and not by way of limitation, drive electrode 20C may be capacitively coupled to sense electrode 22EEE, and the two electrodes may be separated by gap 32C. A ground electrode 30 may extend along an axis parallel to columns of the array and may separate one or more sense electrodes 22A-HHH of one column from drive electrode 20A-C of a different column. Ground electrode 30 may serve to suppress unintentional capacitive coupling between adjacent columns of electrodes. As an example and not by way of limitation, ground electrode 30A may suppress capacitive coupling between sense electrodes 22A-H and drive electrode 20B.

An electrode (whether a drive electrode 20, a sense electrode 22, or a ground electrode 30) may include an area of conductive material forming a shape, such as for example a disc, square, rectangle, thin line, snowflake, other suitable shape, or suitable combination of shapes. A border of an electrode may enclose the area of an electrode and may indicate an outline, outer edge, or boundary of an electrode. A border of an electrode may include one or more connected, straight line-segments, one or more connected, curved line-segments, or any suitable combination of connected straight or curved line-segments. Electrode details may include the shape, dimensions, or border of an electrode as well as the spacing, or gap, between adjacent electrodes. Although this disclosure describes or illustrates particular electrodes having particular shapes, borders, and details, this disclosure contemplates any suitable electrodes having any suitable shapes, borders, and details.

FIG. 2B illustrates an example portion 40 of touch sensor 10 from FIG. 2A enlarged to show example details of portions of drive electrode 20A, sense electrode 22D, and gap 32A. In particular embodiments, each drive electrode 20 and sense electrode 22 may include one or more projections 34 that extend from a base electrode portion 36. An electrode projection 34 may include a portion of an electrode that extends outward or away from a base portion 36 of an electrode. A base portion 36 of an electrode may include a portion of an electrode where one or more electrode projections 34 are connected. A projection 34 of a sense electrode 22 may be adjacent to a projection 34 of a corresponding drive electrode 20 forming capacitive coupling edges separated by gap 32. The combination of drive electrodes 20 and sense electrodes 22 with adjacent projections 34 may be referred to as interdigitated or interleaved projections 34 or interdigitated or interleaved electrodes. Projections 34 of a drive electrode 20 and a sense electrode 22 may be interdigitated when one or more projections from a drive electrode 20 and one or more projections from a sense electrode 22 are located adjacent to one another and separated by a gap 32. Projections 34 may be interdigitated or interleaved to increase the number of capacitive coupling edges between one or more sense electrodes and a corresponding drive electrode. In particular embodiments, a drive electrode 20 may be interdigitated with one or more sense electrodes. In the example of FIG. 2A, drive electrode 20A includes multiple electrode projections 34 that are interdigitated with corresponding electrode projections 34 of sense electrodes 22A-H, and interdigitated projections 34 are separated by gap 32A. In the example of FIG. 2B, drive electrode 20A and sense electrode 22D are interdigitated. In the example of FIG. 2B, projection 34B of sense electrode 22D is interdigitated with projections 34A and 34C of corresponding drive electrode 20A, and projection 34C of drive electrode 20A is interdigitated with projections 34B and 34D of corresponding sense electrode 22D. Capacitive coupling between sense electrode 22D and corresponding drive electrode 20A may be determined by dimensions of gap 32A and borders of projections 34 or base portions 36 of electrodes. Although this disclosure describes and illustrates particular electrodes having a particular number and shape of projections 34 and base portions 36, this disclosure contemplates any suitable arrangements of electrodes having any suitable number and shape of projections 34 and base portions 36.

A gap 32 may be a space or region that separates an adjacent drive and sense electrode. Drive and sense electrodes may be capacitively coupled to each other across a gap 32 between them. As illustrated in FIG. 2B, drive electrode 20A and sense electrode 22D are separated by gap 32A. The separation distance between drive and sense electrodes may be indicated by width 38 of gap 32A. In particular embodiments, a gap 32 may form a separating region between one or more drive and one or more corresponding sense electrodes, and a gap 32 may extend across a portion of or may extend across substantially all of a touch-sensitive area of touch sensor 10. As illustrated in FIG. 2A, gap 32A has an extent from the top to the bottom of drive electrode 20A and forms a separating region between drive electrode 20A and corresponding sense electrodes 20A-H. In the example of FIG. 2A, the entire extent of gap 32A includes the regions between drive electrode 20A and sense electrodes 20A-H. In particular embodiments, the shape and dimensions of a gap 32 may depend on the shape and dimensions of the electrodes that border gap 32.

In particular embodiments, gap 32 between drive and sense electrodes may have a width 38 that is substantially uniform or constant throughout the entire extent of gap 32. In particular embodiments, electrode details may refer to particular shapes or borders of electrodes, electrode protrusions, electrode base regions, or other electrode regions. In particular embodiments, a gap width 38 that is substantially uniform may be achieved by having electrode details where borders facing gap 32 include curved or rounded segments. In particular embodiments, borders facing gap 32 may include curved or rounded segments connected to straight-line segments. As illustrated in FIG. 2B, borders of electrode projections 34 that face gap 32A include curved segments, and the corresponding borders of electrodes facing projections 34 are also similarly curved to produce a substantially uniform width 38. In particular embodiments, the two radii of curvature of two curved border portions that face each other across gap 32 may be different and may be selected so that gap width 38 remains constant across the extent of gap 32. In particular embodiments, a gap width 38 that is substantially uniform may be achieved by having electrode details with borders that are chamfered, beveled, or curved so that the portion of electrode border that faces gap 32 may not include for example, sharp corners or right angles. In particular embodiments, a chamfer or bevel may include a single straight-line segment or multiple straight-line segments connected together. In particular embodiments, an electrode detail may include multiple straight-line segments connected together. In particular embodiments, an electrode detail may include multiple straight-line segments connected together to form a border that approximates a curve. In particular embodiments, an electrode detail may include one or more straight line-segments in combination with one or more curved line-segments. Although this disclosure describes or illustrates particular electrodes having particular details or shapes that may produce a substantially uniform width 38 of gap 32 between electrodes, this disclosure contemplates any suitable electrodes having any suitable details or shapes that may produce a substantially uniform gap width 38.

In particular embodiments, gap width 38 may be approximately 30 μm, 100 μm, 200 μm, 400 μm, or 500 μm. In particular embodiments, gap width 38 of a gap 32 may be considered uniform if it varies by a maximum of, for example, 5% or 10% throughout the entire extent of gap 32. In particular embodiments, a percentage variation (Variation[%]) of a gap width 38 may be expressed as

$$Variation [ \% ] = 100 \times \frac{{GW}_{MAX} - {GW}_{MIN}}{{GW}_{NOMINAL}} ,$$

where GW_{MAX} is a maximum gap width of gap 32, GW_{MIN} is a minimum gap width, and GW_{NOMINAL} is a nominal gap width. As an example and not by way of limitation, a gap 32 having a nominal gap width 38 of approximately 100 μm may exhibit a variation in width 38 between approximately 95 μm and 105 μm throughout the extent of a gap 32, and such a gap 32 may be considered to have a gap width variation of approximately 10%. Although this disclosure describes and illustrates particular gaps 32 having particular shapes, widths 38, and width variation, this disclosure contemplates any suitable gap 32 having any suitable shape or width 38 and any suitable variation of width 38.

In particular embodiments, gap 32 between drive and sense electrodes of a touch sensor 10 may have a width 38 that is substantially uniform or constant throughout a substantial portion of touch sensor 10. In particular embodiments, electrodes of a touch sensor 10 may include portions with two or more distinct gap widths 38. As an example and not by way of limitation, a touch sensor 10 may have a portion with a gap 32 having a gap width 38 of approximately 200 μm and another portion with a gap 32 having a gap width 38 of approximately 400 μm. This disclosure contemplates any suitable touch sensors 10 that include any suitable gaps 32 having one or more distinct gap widths 38.

The example electrodes in FIGS. 2A and 2B may have a single-layer configuration, where drive electrodes 20 and sense electrodes 22 may be disposed on the same side of a substrate. In particular embodiments, touch sensor 10 may have a two-layer (or dual-layer) configuration, where drive electrodes 20 and sense electrodes 22 may be disposed on opposite surfaces of a substrate or on one surface of two different substrates. In such a two-layer configuration, drive and sense electrodes may lie in one of two planes, and the planes may be parallel. In particular embodiments, for a two-layer configuration, reference to a gap 32 or a gap width 38 may be made as if the electrodes lie in a single plane where the two parallel planes were combined together. In particular embodiments, for a two-layer configuration, a gap 32 may be considered to span the space from one plane to another, and gap 32 may not lie in a single plane and may refer to the space or region that connects the borders of corresponding drive and sense electrodes that face each other on either side of gap 32. Moreover, in particular embodiments, for a two-layer configuration, a gap width 38 may refer to the distance between the borders of corresponding drive and sense electrodes that lie in different planes and face each other across gap 32.

In particular embodiments, the region of gap 32 may be substantially filled using the conductive material used to fabricate drive electrodes 20 and sense electrodes 22 in such a way as to electrically isolate the filled-in areas from nearby drive and sense electrodes. In particular embodiments, gaps 32 may be substantially filled using “in-fill” shapes of electrode conductive material isolated from neighboring in-fill shapes by non-conducting gaps. The in-filling may be formed during manufacture and using the same process steps as drive electrodes 20 and sense electrodes 22, such that in-fill shapes may be formed from the same material and may have substantially the same thickness and electrical properties as drive electrodes 20 and sense electrodes 22. In particular embodiments, in-fill shapes may be formed using metal, conductive plastic, ITO, or other form of conductive material, such as fine line metal. The material used to fill in a gap 32 may depend on the conductive material used to fabricate drive electrodes 20 and sense electrodes 22. As an example and not by way of limitation, gaps 32 may be substantially filled in using a series of electrically isolated squares formed during fabrication of drive electrodes 20 and sense electrodes 22. Although this disclosure describes or illustrates particular in-fill shapes having particular patterns, this disclosure contemplates any suitable in-fill shapes having any suitable patterns.

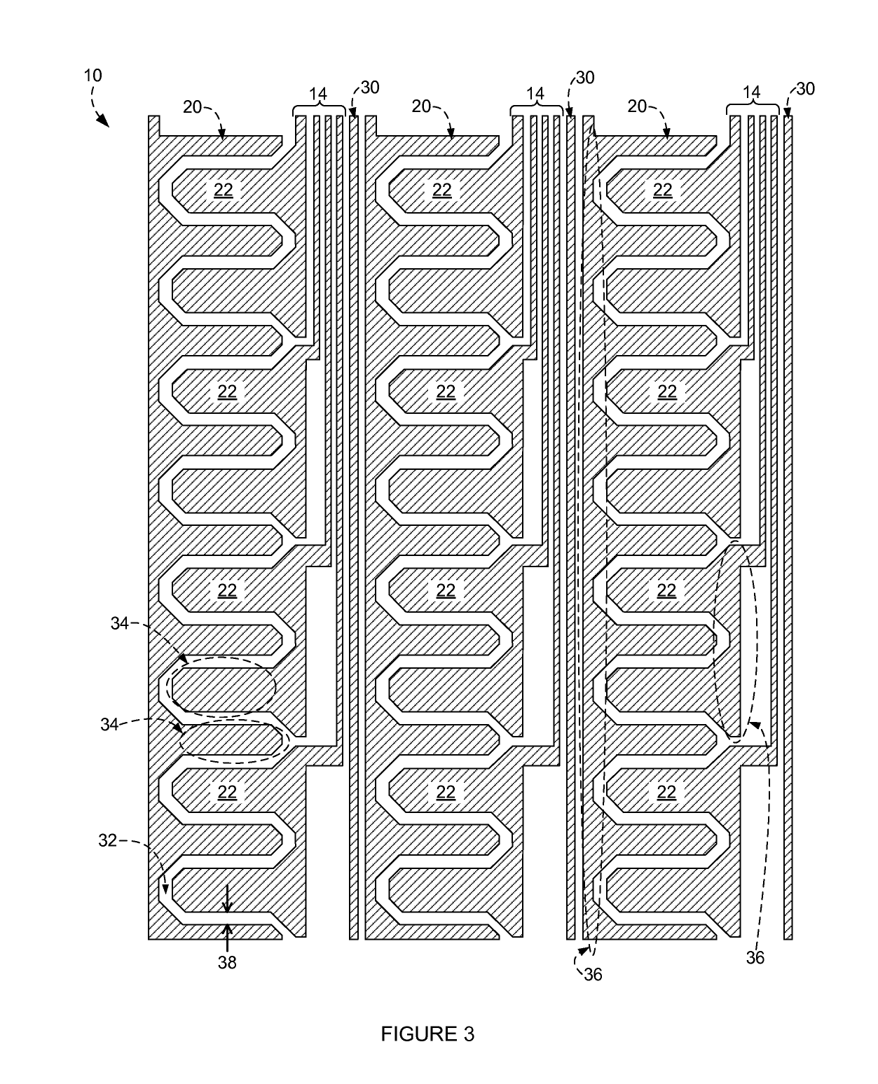

FIG. 3 illustrates another array of example electrodes for an example touch sensor 10. In the example of FIG. 3, adjacent drive electrodes 20 and sense electrodes 22 are separated by gap 32. In the example of FIG. 3, each border of drive electrodes 20 and sense electrodes 22 that faces gap 32 includes multiple straight-line segments connected together. In particular embodiments, straight-line segments may be connected together to remove any sharp corners or right angles that may otherwise appear in an electrode border that faces gap 32. In particular embodiments, straight-line segments may form an electrode border that faces gap 32 where the electrode border may include details that are chamfered or beveled. In particular embodiments, multiple straight-line segments may form a portion of an electrode border so that width 38 of gap 32 is substantially uniform throughout the extent of gap 32. In the example of FIG. 3, each sense electrode includes two projections 34 that extend out from a base electrode portion 36 toward a corresponding drive electrode 20. Similarly, in the example of FIG. 3, each drive electrode 20 includes multiple projections 34 that extend out from base electrode portion 36 toward one or more corresponding sense electrodes 22. In the example of FIG. 3, projections 34 of drive and sense electrodes are interdigitated, and each projection includes a border with multiple straight-line segments connected together to form one or more chamfer details. In the example of FIG. 3, the corresponding border of base portion 36 that faces a chamfered border of a projection is similarly chamfered to produce a gap 32 with a width 38 that is substantially uniform throughout the extent of gap 32. Although this disclosure describes and illustrates particular electrodes having particular shapes formed from particular line-segments that are straight, curved, or a combination of the two, this disclosure contemplates any suitable electrode shapes formed from any suitable straight, curved, or combination of straight and curved line-segments.

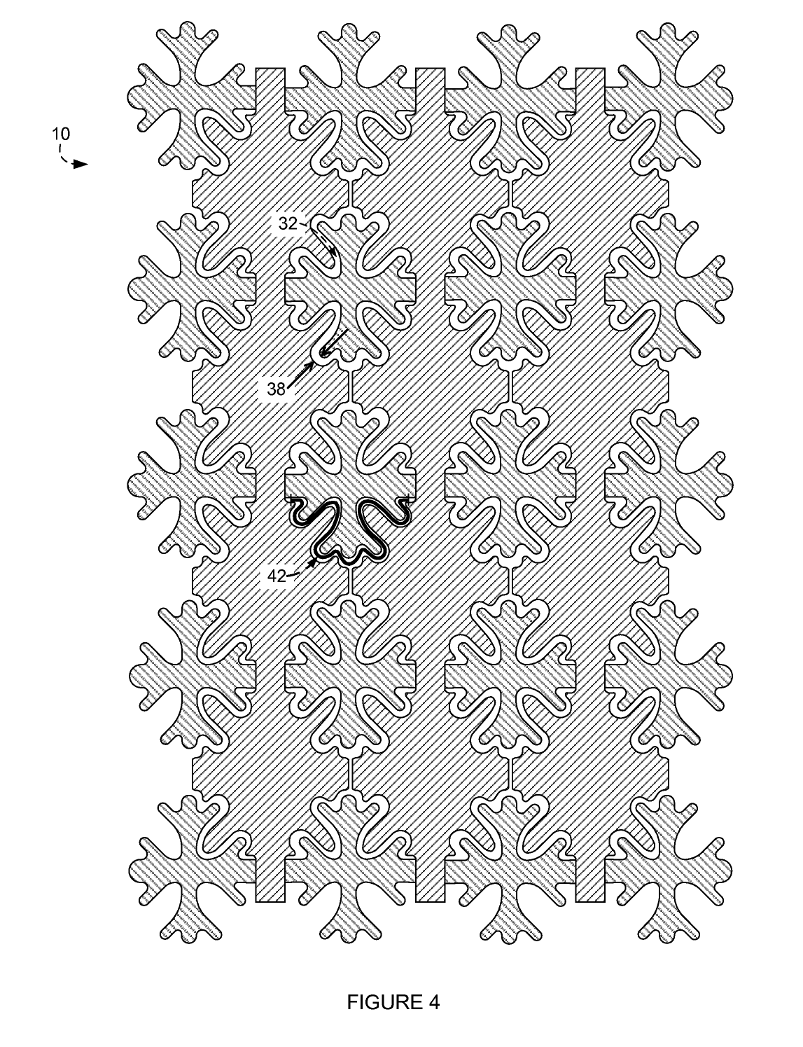

FIG. 4 illustrates another array of example electrodes for an example touch sensor 10. The example electrodes in FIG. 4 may have a dual-layer configuration where the drive and sense electrodes may be disposed on opposite surfaces of a substrate or on one surface of two different substrates. The example electrode array in FIG. 4 may be referred to as a snowflake pattern, where one or more electrodes have a snowflake-like shape. In FIG. 4, the drive and sense electrodes include multiple interdigitated protrusions. In the example of FIG. 4, gap 32 forms the region between drive and sense electrodes, and gap width 38 is substantially uniform. In FIG. 4, the borders of drive and sense electrodes that face gap 32 include multiple curved segments, and the curved segments are shaped so that gap width 38 is substantially uniform throughout the extent 42 of a gap 32. In particular embodiments, gap 32 may not extend into the region where drive and sense electrodes overlap one another. In FIG. 4, as an illustration, the extent 42 of a gap 32 is approximately indicated by a thick line.

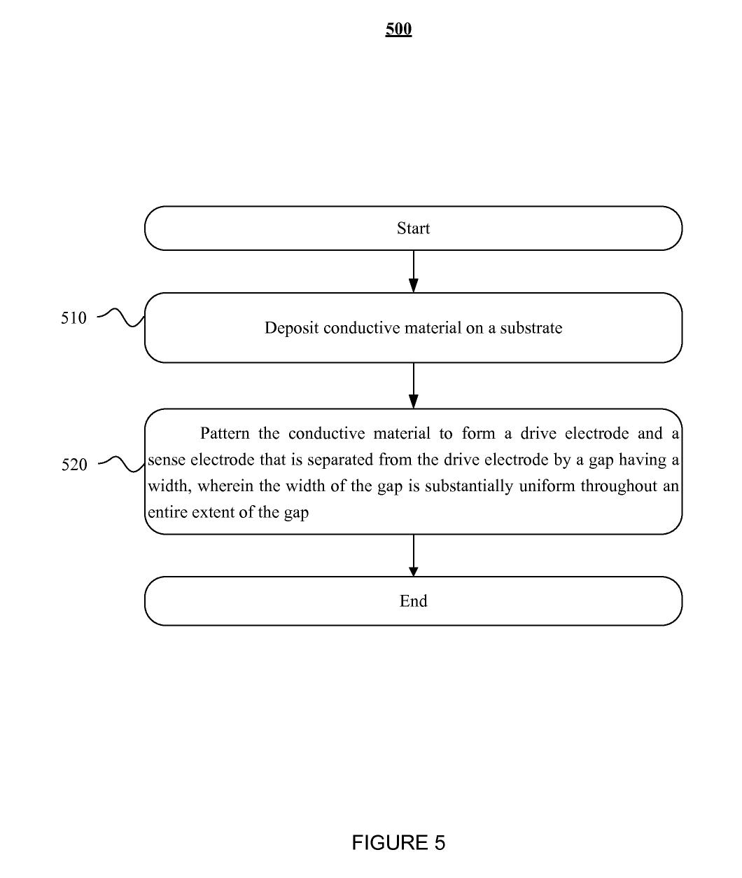

FIG. 5 illustrates an example method for forming drive and sense electrodes. The method may start at step 510 where conductive material may be deposited on a substrate. This disclosure contemplates any suitable deposition technique for depositing conductive material on a substrate, such as for example evaporation, sputtering, physical vapor deposition, or chemical vapor deposition. At step 520, the conductive material may be patterned to form a drive electrode and a sense electrode, at which point the method may end. The sense electrode may be separated from the drive electrode by a gap having a width, and the width of the gap may be substantially uniform throughout the entire extent of the gap. This disclosure contemplates any suitable patterning technique, such as for example photolithography where an electrode pattern is transferred to a layer of photoresist on the conductive material and then the unwanted conductive material is etched away.

Particular embodiments may repeat the steps of the method of FIG. 5, where appropriate. Moreover, although this disclosure describes and illustrates particular steps of the method of FIG. 5 as occurring in a particular order, this disclosure contemplates any suitable steps of the method of FIG. 5 occurring in any suitable order. Furthermore, although this disclosure describes and illustrates particular components, devices, or systems carrying out particular steps of the method of FIG. 5, this disclosure contemplates any suitable combination of any suitable components, devices, or systems carrying out any suitable steps of the method of FIG. 5.

Herein, reference to a computer-readable non-transitory storage medium or media may include one or more semiconductor-based or other integrated circuits (ICs) (such, as for example, a field-programmable gate array (FPGA) or an application-specific IC (ASIC)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards, SECURE DIGITAL drives, any other suitable computer-readable non-transitory storage medium or media, or any suitable combination of two or more of these, where appropriate. A computer-readable non-transitory storage medium or media may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative.

What is claimed is:

1. A touch sensor comprising:
a drive electrode; and
a sense electrode that is separated from the drive electrode by a gap having a width, wherein the width of the gap is substantially uniform throughout an entire extent of the gap.

2. The touch sensor of claim 1, wherein:
the drive and sense electrodes each comprise a border that faces the gap; and
each border comprises one or more curved segments.

3. The touch sensor of claim 1, wherein:
the drive and sense electrodes each comprise a border that faces the gap; and
each border comprises one or more chamfered segments.

4. The touch sensor of claim 1, wherein:
the drive and sense electrodes each comprise a border that faces the gap; and
each border comprises a plurality of connected straight-line segments.

5. The touch sensor of claim 1, wherein:
the drive electrode comprises one or more drive electrode projections;
the sense electrode comprises one or more sense electrode projections; and
one or more drive electrode projections are interdigitated with one or more sense electrode projections.

6. The touch sensor of claim 1, wherein the width of the gap is approximately 100 μm throughout the entire extent of the gap.

7. The touch sensor of claim 1, wherein the width of the gap varies by less than approximately 10% throughout the entire extent of the gap.

8. The touch sensor of claim 1, wherein the electrodes have a snowflake shape.

9. A device comprising:
a touch sensor comprising:
a drive electrode; and
a sense electrode that is separated from the drive electrode by a gap having a width, wherein the width of the gap is substantially uniform throughout an entire extent of the gap; and
a computer-readable non-transitory storage medium embodying logic that is configured when executed to control the touch sensor.

10. The device of claim 9, wherein:
the drive and sense electrodes each comprise a border that faces the gap; and
each border comprises one or more curved segments.

11. The device of claim 9, wherein:
the drive and sense electrodes each comprise a border that faces the gap; and
each border comprises one or more chamfered segments.

12. The device of claim 9, wherein:
the drive and sense electrodes each comprise a border that faces the gap; and
each border comprises a plurality of connected straight-line segments.

13. The device of claim 9, wherein:
the drive electrode comprises one or more drive electrode projections;
the sense electrode comprises one or more sense electrode projections; and
one or more drive electrode projections are interdigitated with one or more sense electrode projections.

14. The device of claim 9, wherein the width of the gap is approximately 100 μm throughout the entire extent of the gap.

15. The device of claim 9, wherein the width of the gap varies by less than approximately 10% throughout the entire extent of the gap.

16. A method comprising:
depositing conductive material on a substrate; and
patterning the conductive material to form a drive electrode and a sense electrode that is separated from the drive electrode by a gap having a width, wherein the width of the gap is substantially uniform throughout an entire extent of the gap.

17. The method of claim 16, wherein:
the drive and sense electrodes each comprise a border that faces the gap; and
each border comprises one or more curved segments.

18. The method of claim 16, wherein:
the drive and sense electrodes each comprise a border that faces the gap; and
each border comprises one or more chamfered segments.

19. The method of claim 16, wherein:
the drive and sense electrodes each comprise a border that faces the gap; and
each border comprises a plurality of connected straight-line segments.

20. The method of claim 16, wherein:
the drive electrode comprises one or more drive electrode projections;
the sense electrode comprises one or more sense electrode projections; and
one or more drive electrode projections are interdigitated with one or more sense electrode projections.
